(19) United States
(12) Patent Application Publication
(10) Pub. No.: US 2026/0031125 A1
(43) Pub. Date: Jan. 29, 2026

(54) MEMORY DEVICE DISTURBANCE MITIGATION USING EXTRA PLATE

(71) Applicant: Micron Technology, Inc., Boise, ID (US)

(72) Inventor: Makoto Kitagawa, Folsom, CA (US)

(21) Appl. No.: 18/786,963

(22) Filed: Jul. 29, 2024

(51) Int. Cl. G11C 11/22

(52) U.S. Cl. CPC G11C 11/2295; G11C 11/2273

(57) ABSTRACT

An electronic device may include multiple plates and multiple plate groups each including a plate of the multiple plates, a memory cell group including memory cells coupled to the plate, and a digit line group including digit lines coupled to respective memory cells of the memory cell group. An extra plate may be positioned near each plate of the multiple plates. When a plate of the multiple plates is selected for a memory cell access operation, the voltage on the selected plate and the voltage on the extra plate positioned near the selected plate may be controlled for mitigation of disturbances of memory cells by reducing crosstalk between the selected plate and one or more adjacent unselected plates.

### BACKGROUND

Memory devices are widely used to store information in various electronic devices such as computers, wireless communication devices, cameras, digital displays, and the like. Information is stored by programming different states of a memory device. For example, binary devices most often store one of two states, often denoted by a logic 1 or a logic 0. To access the stored information, a component of the device may read, or sense, at least one stored state in the memory device. To store information, a component of the device may write, or program, the state in the memory device.

Various types of memory devices exist, including those that employ magnetic hard disks, random access memory (RAM), read only memory (ROM), dynamic RAM (DRAM), synchronous dynamic RAM (SDRAM), ferroelectric RAM (FeRAM), magnetic RAM (MRAM), resistive RAM (RRAM), flash memory, phase change memory (PCM), and others. Memory devices may be volatile or non-volatile. Non-volatile memory, such as PCM and FeRAM, may maintain stored logic states for extended periods of time even in the absence of an external power source. Volatile memory devices, such as DRAM, may lose stored logic states over time unless they are periodically refreshed by a power source. In some cases, non-volatile memory may use similar device architectures as volatile memory but may have non-volatile properties by employing such physical phenomena as ferroelectric capacitance or different material phases.

Improvement of memory devices may include, for example, increasing memory cell density, increasing read/write speeds, increasing reliability, increasing data retention, reducing power consumption, and/or reducing manufacturing costs. When the memory cell density and/or the read/write speeds increase, there is a need to ensure or increase reliability of the memory devices by mitigating disturbances to memory cells caused by signals for accessing an adjacent memory cell.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example of a memory device, according to the present subject matter.

FIG. 2 illustrates an example of a circuit for memory access in a memory device, such as the memory device of FIG. 1, according to the present subject matter.

FIGS. 3A and 3B illustrate examples of non-linear electrical properties with hysteresis plots for a ferroelectric memory cell, such as a ferroelectric memory cell in the memory device of FIG. 1, with FIG. 3A corresponding to a writing process and FIG. 3B corresponding to a reading process, according to the present subject matter.

FIG. 4 illustrates an example of a timing diagram showing selected signals during a memory cell access operation in a memory device, such as the memory device of FIG. 1, according to the present subject matter.

FIG. 5 illustrates an example of portions of a memory device, such as the memory device of FIG. 1, according to the present subject matter.

FIG. 6 illustrates an example of the timing diagram of FIG. 4 showing a cause of disturbance of memory cells, according to the present subject matter.

FIG. 7A illustrates an example of portions of a memory device, such as the memory device of FIG. 5, showing a structure of multiple plates and memory cell groups each coupled between a plate and a group of respective digit lines, according to the present subject matter.

FIG. 7B illustrates an example of portions of a memory device including the memory device of FIG. 7A with multiple extra plates each positioned over a plate of the multiple plates, according to the present subject matter.

FIG. 8 illustrates an example of the timing diagram of FIG. 6 showing an approach to mitigating the disturbance of memory cells, according to the present subject matter.

FIG. 9 illustrates an example of circuitry for driving the plates and extra plates of FIG. 7B, according to the present subject matter.

FIG. 10 illustrates an example of a method for mitigating disturbance of memory cells, according to the present subject matter.

FIG. 11 illustrates an example of simulation results for demonstrating mitigation of the disturbance of memory cells, according to the present subject matter.

FIG. 12 illustrates a block diagram of an example machine with which, in which, or by which any one or more of the techniques discussed herein can be implemented.

### DETAILED DESCRIPTION

In the following detailed description, reference is made to the accompanying drawings which form a part hereof, and in which is shown by way of illustration specific embodiments in which the invention may be practiced. These embodiments are described in sufficient detail to enable those skilled in the art to practice the invention, and it is to be understood that the embodiments may be combined, or that other embodiments may be utilized and that structural, logical and electrical changes may be made without departing from the spirit and scope of the present invention. References to “an”, “one”, or “various” embodiments in this disclosure are not necessarily to the same embodiment, and such references contemplate more than one embodiment. The following detailed description provides examples, and the scope of the present invention is defined by the appended claims and their legal equivalents.

The present disclosure discusses, among other things, a device and method for reducing memory cell disturbances by adding extra plates positioned near (e.g., over) plates in a memory device. Signals in plates change when data is being read from and/or written into memory cells. Such signal changes can cause disturbances through crosstalk between adjacent plates. In an example, such disturbances may be mitigated by controllably charging (or discharging) the extra plates.

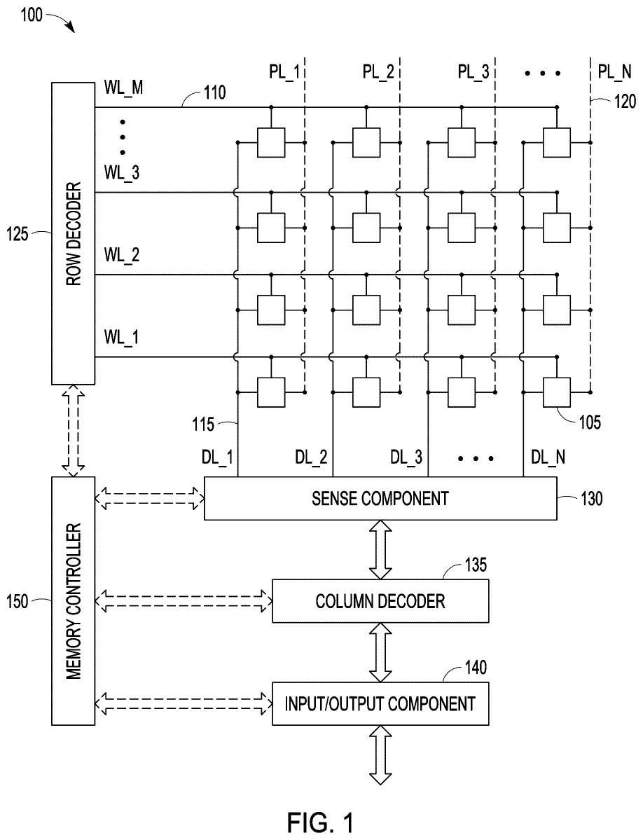

Some types of memory, for example ferroelectric random access memory (FeRAM), use two separate operations in the performance of reading or writing functions. These two separate operations can include sensing and programming operations that comprise setting different access lines (e.g., digit lines, plate lines, and word lines) to relatively high or low levels, as discussed with reference to FIG. 1.

FIG. 1 illustrates an example of a memory device 100 according to the present subject matter. Memory device 100 may also be referred to as an electronic memory apparatus. Memory device 100 includes memory cells 105 that are programmable to store different logic states. In some cases, a memory cell 105 may be programmable to store two logic states, denoted a logic 0 (or “low”) and a logic 1 (or “high”). In some cases, a memory cell 105 may be programmable to store more than two logic states.

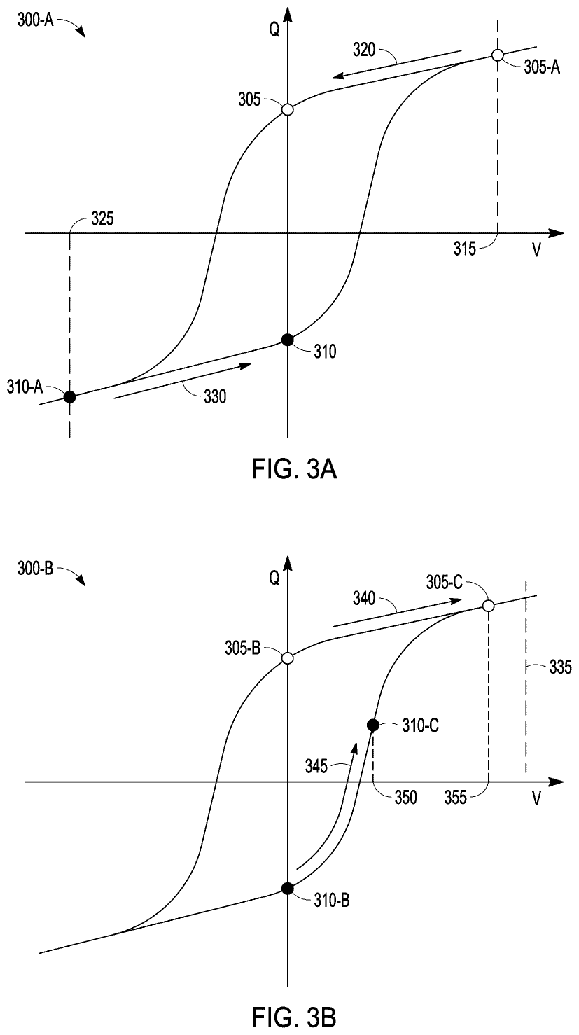

In some examples, a memory cell 105 may store an electrical charge representative of the programmable logic states in a capacitive memory element. For example, a charged and uncharged capacitor of a memory cell 105 may each represent one of two logic states, or a positively charged and a negatively charged capacitor of a memory cell 105 may each represent one of the two logic states. DRAM architectures may commonly use such a design, and the capacitor employed may include a dielectric material with linear or para-electric electric polarization properties as the insulator. In some examples, such as FeRAM architectures, a memory cell 105 may include a ferroelectric capacitor having a ferroelectric material as an insulating layer between terminals of the capacitor. Different levels of polarization of a ferroelectric capacitor may represent different logic states (e.g., supporting two or more logic states in a respective memory cell 105). Ferroelectric materials have non-linear polarization properties including those discussed in further detail below with reference to FIG. 3A and FIG. 3B.

In the example illustrated in FIG. 1, each row of memory cells 105 is coupled with one of a plurality of first access lines 110 (e.g., M word lines, WL_1, WL_2, WL_3, . . . and WL_M, as shown in FIG. 1, also referred to as row lines), and each column of memory cells 105 is coupled with one of a plurality of second access lines 115 (e.g., N digit lines, DL_1, DL_2, DL_3, . . . and DL_N, as shown in FIG. 1, also referred to as bit lines or column lines). Thus, each memory cell 105 may be located at the intersection of one of first access lines 110 and one of second access lines 115. This intersection may be referred to as an address of that memory cell 105. In some cases, first access lines 110 and second access lines 115 may be substantially perpendicular to one another in memory device 100. References to digit lines and bit lines, or their analogues, are interchangeable without loss of understanding or operation. A memory cell 105 targeted to be accessed may be referred to as targeted memory cell 105 and located at the intersection of an energized or otherwise selected access line 110 and an energized or otherwise selected access line 115. In other words, an access line 110 and an access line 115 may be energized or otherwise selected to access (e.g., read from or write into) a memory cell 105 at their intersection. Other memory cells 105 that are in electronic communication with (e.g., connected to) the same access line 110 or 115 may be referred to as untargeted memory cells 105.

Although the access lines discussed with reference to FIG. 1 are shown as direct lines between memory cells 105 and coupled components, access lines may include other circuit elements, such as capacitors, resistors, transistors, amplifiers, voltage sources, switching components, selection components, and others, which may be used to support access operations including those discussed herein. In some examples, an electrode may be coupled with (e.g., between) a memory cell 105 and an access line 110, or with (e.g., between) a memory cell 105 and an access line 115. The term electrode may refer to an electrical conductor, or other electrical interface between components, and in some cases, may be employed as an electrical contact to a memory cell 105. An electrode may include a trace, wire, conductive line, conductive layer, conductive pad, or the like, that provides a conductive path between elements or components of memory device 100.

In some architectures, the component storing the logic state (e.g., a capacitive memory element) of a memory cell 105 may be electrically isolated from a second access line 115 by a selection component. A first access line 110 may be coupled with and may control the selection component. For example, the selection component may be a transistor and first access line 110 may be coupled with a gate of the transistor. Activating first access line 110 may result in an electrical connection or closed circuit between the component storing the logic state of memory cell 105 and its corresponding second access line 115. The second access line 115 may then be accessed to read and/or write the memory cell 105.

In some examples, memory cells 105 may also be coupled with one of a plurality of third access lines 120 (e.g., N plate lines, PL_1, PL_2, PL_3, . . . and PL_N, as shown in FIG. 1). In some examples, the plurality of third access lines 120 may couple memory cells 105 with a voltage source for various reading and/or writing operations including those discussed herein. For example, when a memory cell 105 employs a capacitor for storing a logic state, a second access line 115 may provide access to a first terminal of the capacitor, and a third access line 120 may provide access to a second terminal of the capacitor. As used herein, the term “terminal” need not suggest a physical boundary or connection point of a capacitor of a memory cell 105. Rather, “terminal” may refer to a reference point of a circuit relevant to the capacitor of the memory cell, which may also be referred to as a “node” or “reference point.” Although the plurality of third access lines 120 of the memory device 100 are shown as substantially parallel with the plurality of second access lines 115, in other examples a plurality of third access lines 120 may be substantially parallel with the plurality of first access lines 110, or in any other configuration.

Access operations such as reading, writing, and rewriting may be performed on a memory cell 105 by activating or selecting a first access line 110, a second access line 115, and/or a third access line 120 coupled with the memory cell 105, which may include applying a voltage, a charge, and/or a current to the respective access line. Access lines 110, 115, and 120 may be made of conductive materials, such as metals (e.g., copper (Cu), silver (Ag), aluminum (Al), gold (Au), tungsten (W), titanium (Ti), etc.), metal alloys, carbon, or other conductive materials, alloys, or compounds. Upon selecting a memory cell 105, a resulting signal may be used to determine the stored logic state. For example, a memory cell 105 with a capacitive memory element storing a logic state may be selected, and the resulting flow of charge via an access line and/or resulting voltage of an access line may be detected to determine the programmed logic state of the memory cell 105.

Access to memory cells 105 may be controlled through a row decoder 125 and a column decoder 135. For example, a row decoder 125 may receive a row address from a memory controller 150 and activate the appropriate first access line 110 based on the received row address. Similarly, a column decoder 135 may receive a column address from memory controller 150 and activate the appropriate second access line 115 based on the received column address. Thus, in some examples a memory cell 105 may be accessed by activating a first access line 110 and a second access line 115.

In some examples, memory controller 150 may control the operations (e.g., read operations, write operations, rewrite operations, and refresh operations, discharge operations) of memory cells 105 through the various components (e.g., row decoder 125, column decoder 135, and a sense component 130). In some cases, one or more of the row decoder 125, column decoder 135, and sense component 130 may be co-located or otherwise included with memory controller 150. Memory controller 150 may generate row and column address signals to activate a desired first access line 110 and second access line 115. Memory controller 150 may also generate or control various voltages or currents used during the operation of memory device 100. For example, memory controller 150 may apply a discharge voltage to a first access line 110 or a second access line 115 after accessing one or more memory cells 105.

In general, the amplitude, shape, or duration of an applied voltage, current, or charge may be adjusted or varied, and may be different for the various operations discussed in operating memory device 100. Further, one, multiple, or all memory cells 105 within memory device 100 may be accessed simultaneously. For example, multiple or all memory cells 105 of memory device 100 may be accessed simultaneously during a reset operation in which all memory cells 105, or a group of memory cells 105, are set to a single logic state.

A memory cell 105 may be read, or sensed, by a sense component 130. For example, sense component 130 may be configured to determine the stored logic state of a memory cell 105 based on a signal generated by accessing that memory cell 105. The signal may include a voltage, an electrical charge, an electrical current, or a combination thereof, and sense component 130 may include voltage sense amplifiers, charge sense amplifiers, current sense amplifiers, or a combination of two or more of such amplifiers.

In some examples, a threshold current may be defined for sensing the logic state stored by a memory cell 105. The threshold current may be set above a current that may pass through that memory cell 105 in response to a read signal when that memory cell 105 stores a first logic state, but equal to or below an expected current through that memory cell 105 in response to the read signal when that memory cell 105 stores a second logic state. For example, the threshold current may be higher than a leakage current of the associated access lines 110 or 115. In some examples, a logic state stored by a memory cell 105 may be determined based on a voltage (e.g., across a shunt resistance) resulting from the current driven by a read pulse. For example, the resulting voltage may be compared to a reference voltage, with a first logic state being detected when the resulting voltage is less than the reference voltage and a second logic state detected when the resulting voltage is greater than the reference voltage.

Sense component 130 may include various switching components, selection components, transistors, amplifiers, capacitors, resistors, or voltage sources to detect and amplify a difference in sensing signals (e.g., a difference between a read voltage and a reference voltage, a difference between a read current and a reference current, or a difference between a read charge and a reference charge), aspects of which, in some examples, may be referred to as latching. In some examples, sense component 130 may include a collection of components (e.g., circuit elements) that may be repeated for each of a set of access lines 115 connected to the sense component 130. For example, sense component 130 may include a separate sensing circuit (e.g., a separate sense amplifier, or a separate signal development circuit) for each of a set of access lines 115 coupled with the sense component 130, such that a logic state may be separately detected for a respective memory cell 105 coupled with a respective one of the set of access lines 115. In various examples, a reference signal source or generated reference signal may be shared between components of memory device 100 (e.g., shared among one or more components of sense components 130, such as separate sensing circuits of sense component 130).

Sense component 130 may be included in a device that includes memory device 100. For example, sense component 130 may be included with other read and write circuits, decoding circuits, or register circuits of the memory that may be coupled to memory device 100. In some examples, the detected logic state of a memory cell 105 may be output through a column decoder 135 as an output. In some examples, sense component 130 may be part of column decoder 135 or row decoder 125. In some examples, sense component 130 may be connected to or otherwise in electronic communication with column decoder 135 or row decoder 125.

Although a single sense component 130 is shown, memory device 100 may include more than one sense component 130. For example, a first sense component 130 may be coupled with a first subset of access lines 115 and a second sense component 130 may be coupled with a second subset of access lines 115 (e.g., different from the first subset of access lines 115). In some examples, such a division of sense components 130 may support parallel (e.g., simultaneous) operation of multiple sense components 130. In some examples, such a division of sense components 130 may support matching sense components 130 having different configurations or characteristics to particular subsets of the memory cells 105 of the memory device (e.g., supporting different types of memory cells 105, supporting different characteristics of subsets of memory cells 105, and/or supporting different characteristics of subsets of access lines 115). Additionally or alternatively, two or more sense components 130 may be coupled with the same set of access lines 115 (e.g., for component redundancy). In some examples, such a configuration may support maintaining functionality to overcome a failure or otherwise poor operation of one of the redundant sense components 130. In some examples, such a configuration may support the ability to select one of the redundant sense components 130 for particular operational characteristics (e.g., as related to power consumption characteristics and/or as related to access speed characteristics for a particular sensing operation).

In ferroelectric memory architectures, accessing a memory cell 105 may degrade or destroy the stored logic state, and rewrite or refresh operations may be performed to return the original logic state to that memory cell 105. In DRAM or FeRAM, for example, a capacitor of a memory cell 105 may be partially or completely discharged during a sense operation, thereby corrupting the logic state that was stored in that memory cell 105. Thus, in some examples, the logic state stored in a memory cell 105 may be rewritten after an access operation. Further, activating a single access line 110 or 115 may result in the discharge of all memory cells 105 coupled with the access line 110 or 115. Thus, several or all memory cells 105 coupled with an access line 110 or 115 of an access operation (e.g., all cells of an accessed row, all cells of an accessed column) may be rewritten after the access operation.

A ferroelectric memory element (e.g., a ferroelectric capacitor) of a memory cell 105 may be written by applying a voltage with a magnitude high enough to polarize the ferroelectric memory element (e.g., applying a saturation voltage) with a polarization associated with a desired logic state, and the ferroelectric memory element may be isolated (e.g., floating), or a zero net voltage may be applied across the ferroelectric memory element (e.g., by grounding or virtually grounding the ferroelectric memory element).

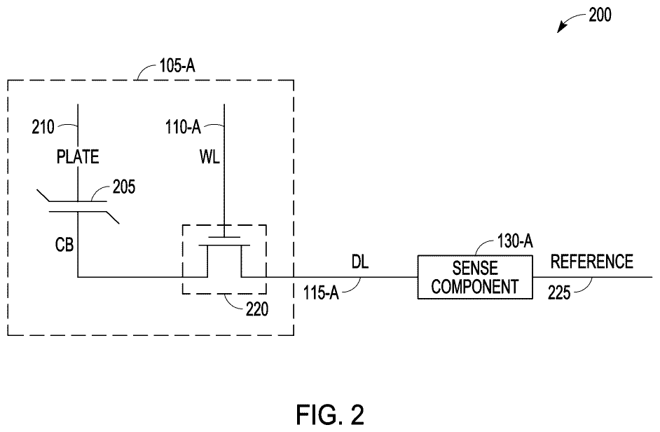

FIG. 2 illustrates an example of a circuit 200 for memory access in a memory device, such as memory device 100, according to the present subject matter. Circuit 200 may include a ferroelectric memory cell 105-A, a word line 110-A (“WL” as shown in FIG. 2), a digit line 115-A (“DL” shown in FIG. 2), and a sense component 130-A, which may respectively be an example of memory cells 105, an example of access lines 110, an example of access lines 115, and an example of sense component 130 or a portion thereof. Circuit 200 includes a logic storage component, such as a capacitor 205 that includes two conductive terminals, a cell plate 210 (“Plate” as shown in FIG. 2) and a cell bottom 215 (“CB” as shown in FIG. 2). These terminals may be separated by an insulating ferroelectric material. As discussed above, various logic states may be stored by charging or discharging capacitor 205. Cell plate 210 may correspond to an example of plate lines 120 and therefore may also be referred to as plate line 210.

The stored logic state of capacitor 205 may be read, or sensed, by operating various elements of circuit 200. Capacitor 205 may be in electronic communication with digit line 115-A. Capacitor 205 may be isolated from the digit line 115-A when selection component 220 is deactivated, and capacitor 205 may be connected to digit line 115-A via selection component 220 when selection component 220 is activated. In some cases, selection component 220 may be a transistor and its operation may be controlled by applying a voltage to the transistor gate through word line 110-A, with the magnitude of the applied voltage being greater than the threshold magnitude of the transistor. For example, a voltage applied to word line 110-A and hence the transistor gate may activate selection component 220, thereby connecting capacitor 205 with digit line 115-A.

In some examples, capacitor 205 is a ferroelectric capacitor. The change in stored charge depends on the initial state of capacitor 205, i.e., whether the initial state corresponds to a logic 1 or a logic 0. The change in charge stored in capacitor 205 may then be compared to a reference (e.g., a reference voltage) by sense component 130-A in order to determine the logic state stored in memory cell 105-A. To write memory cell 105-A, a voltage may be applied across capacitor 205.

FIG. 3A and FIG. 3B illustrate examples of non-linear electrical properties with hysteresis plots for a ferroelectric memory cell in a memory device, such as memory device 100, according to the present subject matter. Hysteresis curves 300-A, shown in FIG. 3A, and 300-B, shown in FIG. B, illustrate an example of writing and reading process, respectively, for a ferroelectric memory cell, such as memory cell 105-A. Hysteresis curves 300 depict the charge, Q, stored on a ferroelectric capacitor, such as capacitor 205, as a function of a voltage difference, V, applied on the ferroelectric capacitor.

A ferroelectric material is characterized by a spontaneous electric polarization. For example, the ferroelectric material maintains a non-zero electric polarization in the absence of an electric field. Examples of the ferroelectric material include barium titanate (BaTiO3), lead titanate (PbTiO3), lead zirconium titanate (PZT), and strontium bismuth tantalate (SBT). The ferroelectric capacitors described herein may include these or other ferroelectric materials. Electric polarization within a ferroelectric capacitor results in a net charge at the ferroelectric material's surface and attracts opposite charge through the capacitor terminals. Thus, charge is stored at the interface of the ferroelectric material and the capacitor terminals. Because the electric polarization may be maintained in the absence of an externally applied electric field for relatively long times, charge leakage may be significantly decreased as compared with, for example, capacitors employed in volatile memory arrays. This may reduce the need to perform refresh operations as described above for some volatile memory architectures.

Hysteresis curves 300 may be understood from the perspective of a single terminal of a capacitor. By way of example, if the ferroelectric material has a negative polarization, positive charge accumulates at the terminal. Likewise, if the ferroelectric material has a positive polarization, negative charge accumulates at the terminal. Additionally, it should be understood that the voltages in hysteresis curves 300 represent a voltage difference across the capacitor and are directional. For example, a positive voltage may be realized by applying a positive voltage to the terminal and maintaining the other terminal at ground (or approximately 0 V). A negative voltage may be applied by maintaining the terminal at ground and applying a positive voltage to the other terminal. Similarly, two positive voltages, two negative voltages, or any combination of positive and negative voltages may be applied to the appropriate capacitor terminals to generate the voltage difference shown in hysteresis curves 300.

As shown in hysteresis curve 300-A, the ferroelectric material may maintain a positive or negative polarization with a zero-voltage difference, resulting in two possible charged states: charge state 305-A and charge state 310-A. In the example of FIG. 3A, charge state 305 represents a logic 0 and charge state 310 represents a logic 1. In some examples, the logic values of the respective charge states may be reversed without loss of understanding.

A logic 0 or 1 may be written to the memory cell by controlling the electric polarization of the ferroelectric material, and thus the charge on the capacitor terminals, by applying a voltage. For example, applying a net positive voltage 315 across the capacitor results in charge accumulation until charge state 305-A is reached. Upon removing voltage 315, charge state 305-A follows path 320 until it reaches charge state 305 at zero voltage potential. Similarly, charge state 310 is written by applying a net negative voltage 325, which results in charge state 310-A. After removing negative voltage 325, charge state 310-A follows path 330 until it reaches charge state 310 at zero voltage. In some example aspects, after sensing, stored data in a cell is destroyed (e.g., written to “0” regardless of the original data). Accordingly, if a “0” is to be programmed into the cell, no further action is needed. However, if a “1” is to be programmed into the cell, then writing a “1” as described above may occur.

To read, or sense, the stored state of the ferroelectric capacitor, a voltage may be applied across the capacitor. In response, the stored charge changes, and the degree of the change depends on the initial charge state, i.e., the degree to which the stored charge of the capacitor changes varies depending on whether charge state 305-B or 310-B was initially stored. For example, hysteresis curve 300-B illustrates two possible stored charge states 305-B and 310-B. Net voltage 335 may be applied across the capacitor. Although depicted as a positive voltage, voltage 335 may be negative. In response to voltage 335, charge state 305-B may follow path 340. Likewise, if charge state 310-B was initially stored, then it follows path 345. The final position of charge state 305-C and charge state 310-C depend on a number of factors, including the specific sensing operation and circuitry.

In some cases, the final charge may depend on the intrinsic capacitance of the digit line of a memory cell. For example, if the capacitor is electrically connected to the digit line and voltage 335 is applied, the voltage of the digit line may rise due to its intrinsic capacitance. Therefore, a voltage measured at a sense component may not equal voltage 335 and instead may depend on the voltage of the digit line. The position of final charge states 305-C and 310-C on hysteresis curve 300-B may thus depend on the capacitance of the digit line and may be determined through a load-line analysis, i.e., charge states 305-C and 310-C may be defined with respect to the digit line capacitance. As a result, the voltage of the capacitor, voltage 350 or voltage 355, may be different and may depend on the initial state of the capacitor. By comparing voltage 350 or voltage 355 to a reference voltage, the initial state of the capacitor may be determined. For example, the reference voltage may be an average of voltage 350 and 355 and, upon comparison, the sensed voltage may be determined to be higher or lower than the reference voltage. A value of the ferroelectric cell (i.e., a logic 0 or 1) may then be determined based on the comparison.

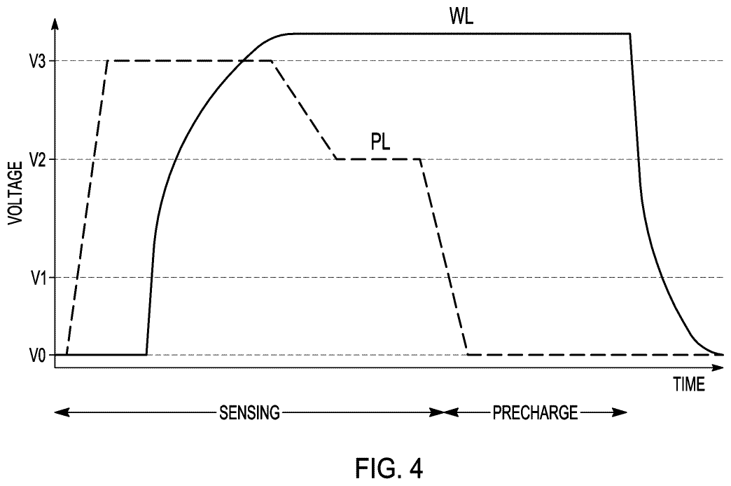

FIG. 4 illustrates an example of a timing diagram showing selected signals during an access operation in a memory device, such as memory device 100, according to the present subject matter. An access operation performed on a selected ferroelectric memory cell includes two phases: a sensing phase (during which a voltage difference is applied to the capacitive component, the logic state of the memory cell is sensed, and written back if applicable) and a precharge phase (during which the voltage difference returns to zero, and the memory cell returns to a stable logic state), as illustrated in FIGS. 3B and 4. During the sensing-precharge sequence for which a plate is selected, the plate voltage may rise and fall while the word line voltage stays high (selected). For example, as shown in FIG. 4, during a digit line low sensing, while the word line voltage (WL) is high, the plate voltage (PL) falls from V3 to V2 during the sensing phase and falls from V2 to V0 during the precharge phase. The change of the plate voltage may cause disturbance in the selected word line and unselected digit lines.

A digit line may be shorted to a respective plate during the access operation, as controlled by a memory controller (e.g., memory controller 150), to reduce the disturbance to the memory cell on a selected word line and unselected digit lines. An example of such an approach to mitigating disturbances of memory cell is discussed in U.S. Patent Application Publication No. 2019/0043595 A1, assigned to Micron Technology, Inc., which is incorporated herein by reference in its entirety. This approach may be applied to avoid the disturbance in the selected word line and unselected digit lines when the voltage in the selected plate changes. However, crosstalk between the selected plate and one or more adjacent unselected plates may still cause disturbance of memory cells, as discussed below.

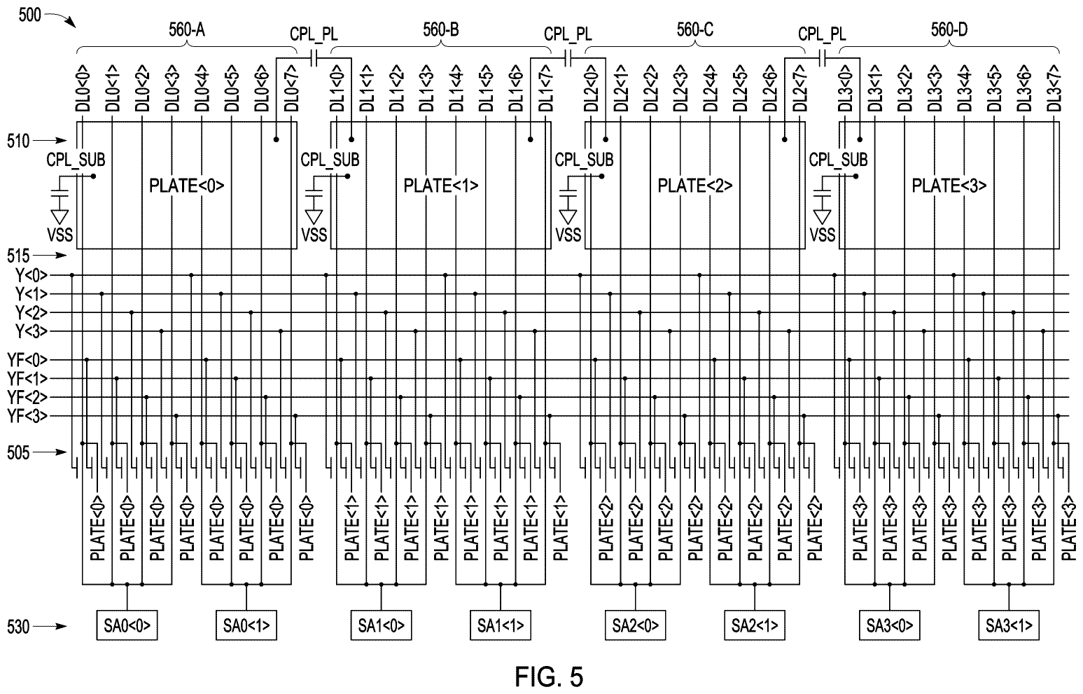

FIG. 5 illustrates an example of portions of a memory device 500, which may represent an example of memory device 100, according to the present subject matter. The portions of memory device 500 as shown in FIG. 5 include multiple plates (PLs) 510, multiple digit lines (DLs) 515; multiple memory cells 505, and multiple sensing amplifiers (SAs) 530. In the illustrated example, these elements of memory device 500 are arranged according to an array architecture that include multiple plate groups 560, with plate groups 560-A, 560-B, 560-C, and 560-D shown as examples. Memory device 500 may include any number of such plate groups. Plate groups 560 may each include a particular plate of multiple plates 510, a memory cell group including memory cells of memory cells 505 that are coupled to the plate, a digit line group including digit lines of digital lines 515 that are respectively coupled to the memory cells, and a sense amplifier group including sense amplifiers of sense amplifiers 530 that are respectively coupled to the memory cells through the digit lines.

For example, plate group 560-A may include the memory cell group of 8 memory cells of memory cells 505 coupled to a plate<0> and coupled to respective sense amplifiers SA0<0> and SA0<1> of the sense amplifier group through respective digit lines DL0<0>-<7> of the digit line group. The 8 memory cells may include capacitive elements and respective selection components, such as illustrated by memory cell 105-A in FIG. 2. The capacitive elements may each be a ferroelectric capacitor and may be coupled to plate<0> directly and coupled to respective digit lines DL0<0>-<7> through the respective selection components. The selection component may be driven by complementary selection lines Y<0> and YF<0>, which may be driven by one or more word lines of memory device 500. Similarly, plate group 560-B may include the memory cell group of 8 memory cells of memory cells 505 coupled to a plate<1> and coupled to respective sense amplifiers SA1<0> and SA1<1> of the sense amplifier group through respective digit lines DL1<0>-<7> of the digit line group. The 8 memory cells may include capacitive elements and respective selection components, such illustrated by memory cell 105-A in FIG. 2. The capacitive elements may each be a ferroelectric capacitor and may be coupled to plate<1> directly and coupled to respective digit lines DL1<0>-<7> through the respective selection components. The selection component may be driven by complementary selection lines Y<1> and YF<1>, which may be driven by one or more word lines of memory device 400. Plate groups 560-C and 560D also each include corresponding components arranged in the same manner. An example of such an array architecture of a memory device is discussed in U.S. Patent Application Publication No. 2021/0142862 A1.

Also shown in FIG. 5 are instances of capacitance between each plate and substrate (e.g., ground), also referred to as plate capacitance (CPL_sub), and coupling capacitance between each pair of adjacent plates (CPL_PL). These capacitances contribute to disturbances of memory cells because of crosstalk between adjacent plates. For example, when plate<1> is selected for an access operation, the voltage on plate<1> changes. This voltage change may cause a glitch in each of plate <0> and plate <2>, which are unselected (and therefore their voltages should remain unchanged while plate<1> is selected during the access operation).

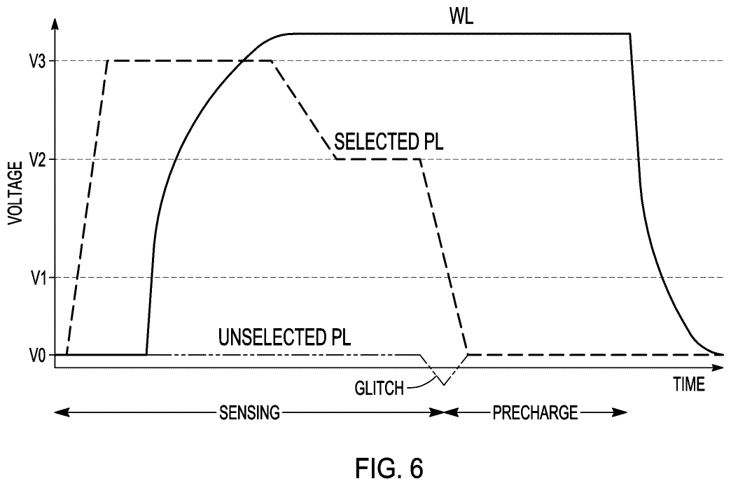

FIG. 6 illustrates an example of the timing diagram of FIG. 4 showing a cause of disturbance of memory cells, according to the present subject matter. In addition to the voltages of the word line (WL) and the plate (selected PL) shown in FIG. 4, the voltage of an unselected plate (unselected PL) is shown in the timing diagram FIG. 6.

In the example of FIG. 5, one of the four plates is selected for a sensing-precharge sequence, and the voltage of the selected plate rises and falls during the sensing-precharge sequence. When the voltage of the selected plate rises and falls, all the digit lines associated with that plate are shorted to that plate (e.g., via digit line multiplexers). Thus, even though the word line is high when the voltage of the selected plate rises and falls, no disturbance results from voltage differences between the plate and digit lines or between the digit lines. Three of the four plates are unselected and driven to Vss during the same sensing-precharge sequence. All the digit lines associated with each unselected plate are shorted to that unselected plate (e.g., via digit line multiplexers). Thus, no disturbance results from voltage differences between the plate and digit lines or between the digit lines.

However, due to the coupling between the selected plate and adjacent unselected plates, a change in the plate voltage of the selected plate may result in a glitch in an adjacent unselected plate via crosstalk between the selected plate and the unselected plate, while no glitch results in the digit lines. Such glitches in the unselected plates may cause disturbance to the memory cells. The magnitude of the disturbance may be strongly dependent on the coupling ratio, which is the ratio of the coupling capacitance between adjacent plates to the sum of the capacitance between plate and substrate and the coupling capacitance between adjacent plates (i.e., (CPL_PL/(CPL_sub+CPL_PL)). The present subject matter can be applied to reduce such crosstalk, and hence the glitches, for mitigation of the disturbance of memory cells.

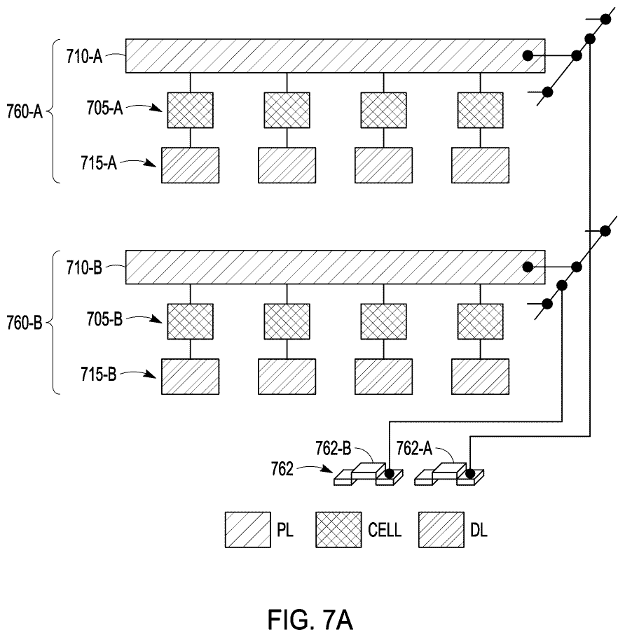

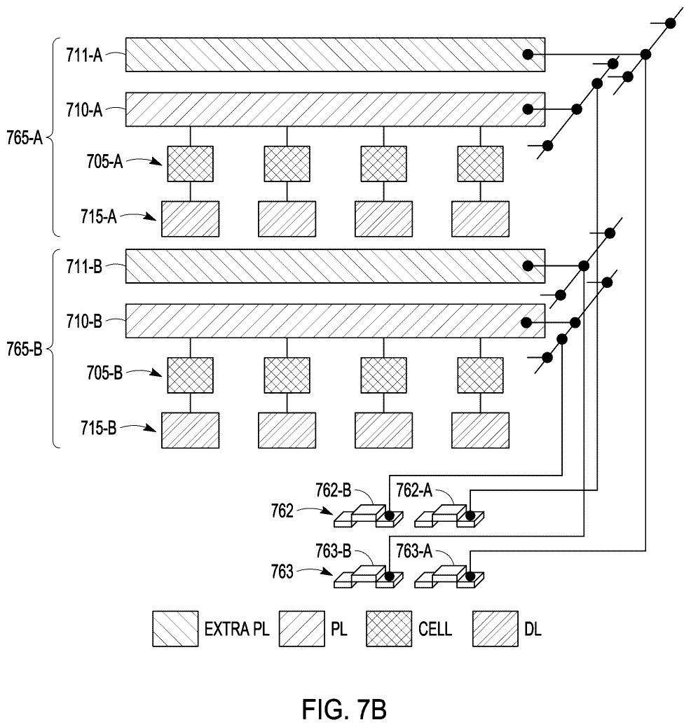

FIG. 7A illustrates an example of portions of a memory device, such as memory device 500, showing a structure of multiple plates and memory cell groups each coupled between a plate and a group of respective digit lines, according to the present subject matter.

Portions of two plate groups, plate groups 760-A and 760-B, are illustrated as an example for illustrative, but not restrictive, purposes. Each of plate groups 760 may represent an example for a plate group of plate groups 560. Also illustrated is a plate driver group 762 showing two plate drivers, plate driver 762-A and plate driver 762-B. Plate group 760-A as shown includes a plate 710-A, a memory cell group 705-A (showing 4 cells for example), and a digit line group 715-A (showing 4 digit lines for example). Cells of memory cell group 705-A are each coupled between plate 710-A and a respective digit line of digit line group 715-A. Plate 710-A is coupled to, and to be driven by, plate driver 762-A. Similarly, plate group 760-B as shown includes a plate 710-B, a memory cell group 705-B (showing 4 cells for example), and a digit line group 715-B (showing 4 digit lines for example). Cells of memory cell group 705-B are each coupled between plate 710-B and a respective digit line of digit line group 715-B. Plate 710-B is coupled to, and to be driven by, plate driver 762-B. Plate drivers 762-A and 762-B may each generate a plate voltage during a memory cell access operation, such as the plate voltage of the selected plate voltage shown in the timing diagram of FIG. 6. Plates 710-A and 710-B may be adjacent to each other such that when one of them is selected and the other is unselected, the change in the plate voltage of the selected plate may result in a glitch in the plate voltage of the unselected plate, such as illustrated in FIG. 6.

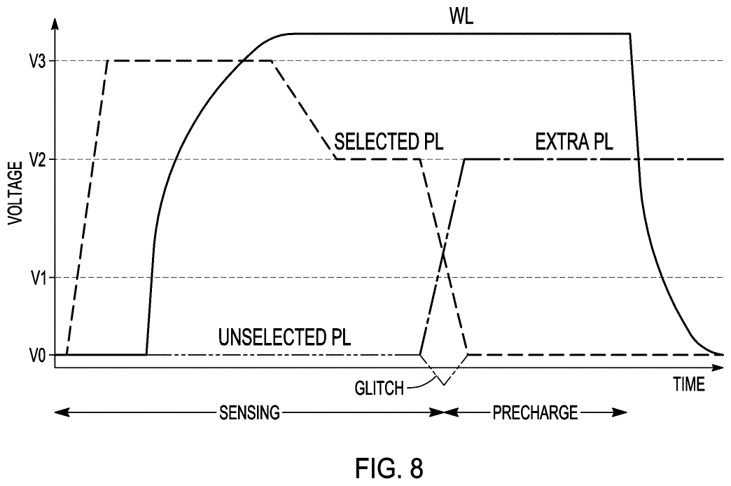

FIG. 7B illustrates an example of portions of a memory device including the memory device of FIG. 7A with multiple extra plates (also referred to as “dummy plates”) 711 each positioned near (e.g., over, or adjacent to, such as with one or more intervening layers in between) a respective plate of multiple plates 710, according to the present subject matter. The multiple extra plates are used to mitigate disturbances of memory cells by reducing the glitches in the unselected plates by placing an extra plate near each plate (e.g., an extra plate layer over each plate). Portions of two plate groups, plate groups 765-A and 765-B, are illustrated as an example for illustrative, but not restrictive, purposes. In addition to plate 710-A, memory cell group 705-A, and digit line group 715-A, plate group 765-A includes an extra plate (or “dummy plate”) 711-A that is positioned near plate 710-A. In addition to plate 710-B, memory cell group 705-B, and digit line group 715-B, plate group 765-B includes an extra plate (or “dummy plate”) 711-B that is positioned near plate 710-B. Also illustrated is an extra plate driver group 763 showing two extra plate drivers, extra plate driver 763-A and extra plate driver 763-B. Extra plate 711-A is coupled to, and to be driven by, extra plate driver 763-A. Extra plate 711-B is coupled to, and to be driven by, extra plate driver 763-B. Extra plate drivers 763-A and 763-B may each generate an extra plate voltage during the memory cell access operation, as discussed below with reference to FIG. 8.

FIG. 8 illustrates an example of the timing diagram of FIG. 6 showing an approach to mitigating the disturbance of memory cells, according to the present subject matter. In addition to the voltages of the word line (WL), the plate (selected PL), the unselected plate (unselected PL), as shown in FIG. 6, the voltage of an extra plate (extra PL) is shown in the timing diagram FIG. 8. The extra plate voltage may be generated by, for example, extra plate driver 763-A or 763-B, whichever is selected to drive the extra plate positioned near the selected one of plate 710-A or 710B. When the plate voltage in the selected plate changes (e.g., falls during a precharge phase as shown in FIG. 8), the extra plate voltage of the extra plate positioned near the selected plate is driven to change in the opposite direction (e.g., rises as the plate voltage falls during the precharge phase as shown in FIG. 8) to cancel the effect of the crosstalk between the selected plate and an unselected plate. The result may include a glitch that is reduced in magnitude (e.g., amplitude and/or duration) and/or an increased slew rate of the plate voltage of the selected plate.

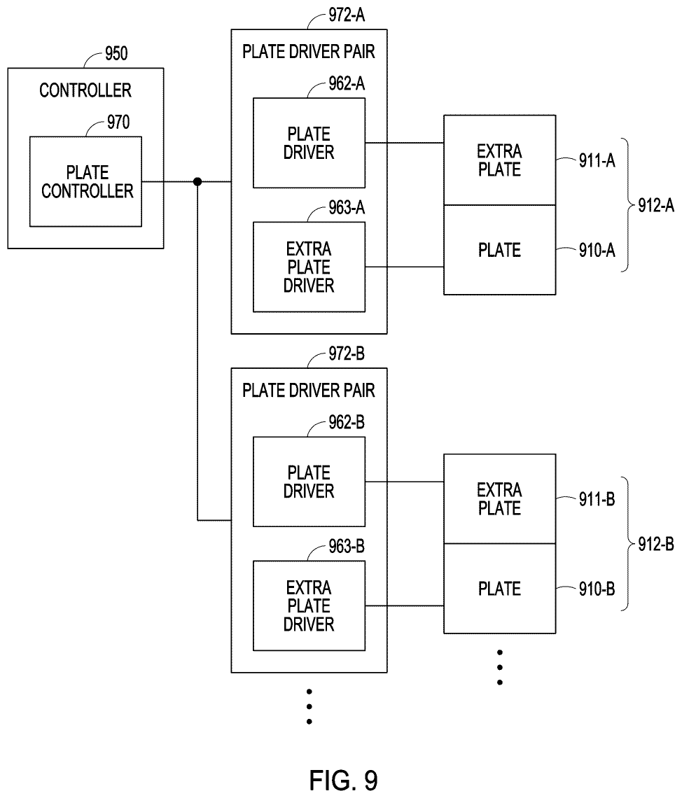

FIG. 9 illustrates an example of circuitry for driving plates and extra plates, such as those illustrated in FIG. 7B, according to the present subject matter. The plates and extra plates are shown as multiple plate-extra plate pairs 912 each including a plate of multiple plates 910 and an extra plate of multiple extra plates 911. For example, plate-extra plate pair 912-A includes a plate 910-A and an extra plate 911-A that is positioned near plate 910-A. Plate-extra plate pair 912-B includes a plate 910-B and an extra plate 911-B that is positioned near plate 910-B. Plates 910 may represent an example of plates 710. Extra plates 911 may represent an example of plates 711. Plate driver 962 may represent an example of plate drivers 762. Extra plate driver 963 may represent an example of extra plate drivers 763.

Each pair of plate-extra plate pairs 912 may be driven by a respective driver pair of multiple driver pairs 972. For example, driver pair 972-A may drive plate-extra plate pair 912-A, and driver pair 972-B may drive plate-extra plate pair 912-B. Driver pairs 972 each include a plate driver 962 and an extra plate driver 963 respectively coupled to a plate 910 and an extra plate 911 of a plate-extra plate pair 912. For example, plate driver 962-A may drive plate 910-A, extra plate driver 963-A may drive extra plate 911-A, plate driver 962-B may drive plate 910-B, and extra plate driver 963-B may drive extra plate 911-B. Plate drivers 962 may each generate a plate signal to be applied to a respective plate 910, resulting in the plate voltage on that respective plate. Extra plate drivers 963 may each generate an extra plate signal to be applied to a respective extra plate 911, resulting in the extra plate voltage on that respective extra plate.

The circuitry may also include a controller 950, which may be an example of memory controller 150 or portions thereof. Controller 950 may select a plate of plates 910 and control a memory cell access operation (e.g., a sensing operation) in the plate group of the selected plate. Plate controller 970 may control the respective plate driver 962 to generate the plate signal to be applied to the selected plate and control the respective extra plate drivers 963 to generate the extra plate signal to be applied to each adjacent unselected plate for reducing crosstalk between the selected plate and each adjacent unselected plate. For example, controller 950 selects plate 910-A. Plate controller 970 then controls plate driver 962-A to generate the plate signal to be applied to plate 910-A and controls extra plate driver 963-A to generate the extra plate signal to be applied to 911-A for reducing crosstalk between plate 910-A and each adjacent unselected plate (e.g., plate 910-B).

The plate signal and the extra plate signal are complementary signals during a portion of the memory cell access operation during which the plate signal changes. For example, when the memory device access operation is a digit line low sensing operation including a sensing phase and a precharge phase, the plate signal falls, and the extra plate signal rises, at the beginning of the precharge phase, such as shown in the timing diagram of FIG. 8. When the memory device access operation is a digit line high sensing operation including a sensing phase and a precharge phase, the plate signal rises, and the extra plate signal falls, at the beginning of the precharge phase.

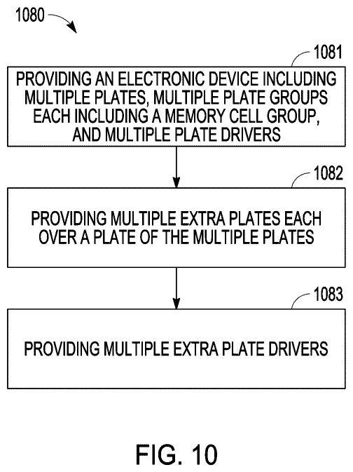

FIG. 10 illustrates an example of a method 1080 for mitigating disturbance of memory cells, according to the present subject matter. Method 1080 may be applied in some of the steps of making an electronic device, such as a memory device, for the purpose of reducing disturbances of memory cells by reducing cross-talk between plates. For example. method 1080 may be applied as part of a process of making a memory device having portions of structure illustrated in FIG. 7B.

At a step 1081, an electronic device is provided. The electronic device may include, among other things, multiple plates, multiple plate groups, and multiple plate drivers. The electronic device may be a memory device such as a FeRAM device. The multiple plate groups may each include a plate of the multiple plates, a memory cell group including memory cells coupled to the plate, and a digit line group including digit lines coupled to respective memory cells of the memory cell group. The multiple plate drivers may each be configured to generate a plate signal to be applied to a plate of the multiple plates.

At a step 1082, multiple extra plates are provided. The multiple extra plate are each an extra plate layer positioned near (e.g., over, or adjacent to, such as with one or more intervening layers in between) a plate of the multiple plates.

At a step 1083, multiple extra plate drivers are provided. The multiple extra plate drivers may each be configured to generate an extra plate signal to be applied an extra plate of the multiple extra plates.

A memory cell access operation may be controlled, for example by a memory controller of the electronic device. During the memory cell access operation, a plate of the multiple plates is selected for accessing one or more of the memory cells coupled to the selected plate. Controlling the memory cell access operation may include controlling generation of the plate signals and the extra plate signals for reducing crosstalk between the selected plate and one or more unselected plates of the multiple plates. The generation of the plate signal and the extra plate signal may be controlled such that the plate signal and the extra plate signal change simultaneously or concurrently during a portion of the memory cell access operation. The generation of the plate signal and the extra plate signal may be controlled such that the plate signal and the extra plate signal are complementary signals during a portion of the memory cell access operation. The memory cell access operation may be a sensing operation including a sensing phase and a precharge phase. In one example of a sensing operation (e.g., a plate low sensing operation), the plate signal and the extra plate signal may be generated to be applied to the selected plate and the extra plate positioned near the selected plate, respectively, such that the plate signal falls, and the extra plate signal rises, at a beginning of the precharge phase. In another example of a sensing operation (e.g., a plate high sensing operation), the plate signal and the extra plate signal may be generated to be applied to the selected plate and the extra plate positioned near the selected plate, respectively, such that the plate signal rises, and the extra plate signal falls, at a beginning of the precharge phase.

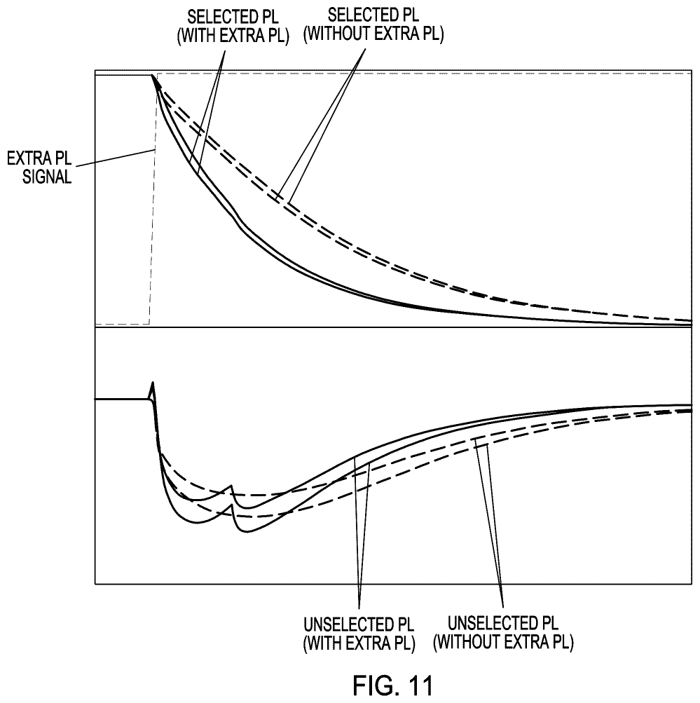

FIG. 11 illustrates an example of simulation results for demonstrating mitigation of the disturbance of memory cells, according to the present subject matter. FIG. 11 shows an extra plate (PL) signal that rises (e.g., at the beginning of the precharge phase of a digit line low sensing operation), the plate voltage on a selected plate (selected PL) with and without the extra plate (extra PL), and the glitch on an unselected plate (unselected PL) with and without the extra plate (extra PL). The simulation results show that the use of the extra plate voltage increases the slew rate of the falling plate voltage of the selected plate and reduces the duration of each glitch in the unselected plate, while the amplitude of each glitch in the unselected plate is not significantly changed.

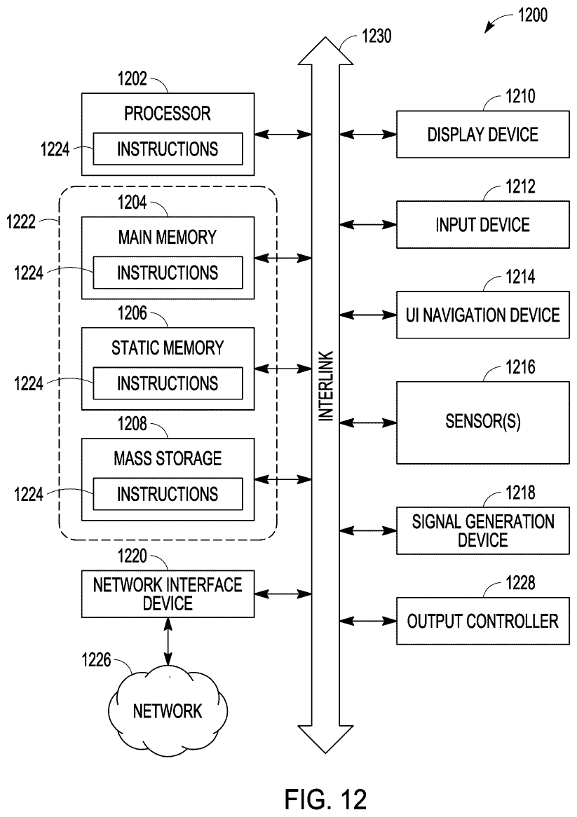

FIG. 12 illustrates a block diagram of an example machine 1200 with which, in which, or by which any one or more of the techniques (e.g., circuits or methods) discussed herein can be implemented. Examples, as discussed herein, can include, or can operate by, logic or a number of components, or mechanisms in the machine 1200. Circuitry (e.g., processing circuitry) is a collection of circuits implemented in tangible entities of the machine 1200 that include hardware (e.g., simple circuits, gates, logic, etc.). Circuitry membership can be flexible over time. Circuitries include members that can, alone or in combination, perform specified operations when operating. In an example, the hardware of the circuitry can include variably connected physical components (e.g., execution units, transistors, simple circuits, etc.) including a machine-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, in an example, the machine-readable medium elements are part of the circuitry or are communicatively coupled to the other components of the circuitry when the device is operating. In an example, any of the physical components can be used in more than one member of more than one circuitry. For example, under operation, execution units can be used in a first circuit of a first circuitry at one point in time and reused by a second circuit in the first circuitry, or by a third circuit in a second circuitry at a different time.

In alternative embodiments, the machine 1200 can operate as a standalone device or can be connected (e.g., networked) to other machines. In a networked deployment, the machine 1200 can operate in the capacity of a server machine, a client machine, or both in server-client network environments. In an example, the machine 1200 can act as a peer machine in peer-to-peer (P2P) (or other distributed) network environment. The machine 1200 can be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

The machine 1200 (e.g., computer system) can include a hardware processor 1202 or host device (e.g., a central processing unit (CPU), a graphics processing unit (GPU), a hardware processor core, or any combination thereof), a main memory 1204, a static memory 1206 (e.g., memory or storage for firmware, microcode, a basic-input-output (BIOS), unified extensible firmware interface (UEFI), etc.), and mass storage device 1208 or memory die stack (e.g., a memory die stack, hard drives, tape drives, flash storage, or other block devices) some or all of which can communicate with each other via an interlink 1230 (e.g., bus). The machine 1200 can further include a display device 1210, an alphanumeric input device 1212 (e.g., a keyboard), and a user interface (UI) Navigation device 1214 (e.g., a mouse). In an example, the display device 1210, the input device 1212, and the UI navigation device 1214 can be a touch screen display. The machine 1200 can additionally include a mass storage device 1208 (e.g., a drive unit), a signal generation device 1218 (e.g., a speaker), a network interface device 1220, and one or more sensor(s) 1216, such as a global positioning system (GPS) sensor, compass, accelerometer, or other sensor. The machine 1200 can include an output controller 1228, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Registers of the hardware processor 1202, the main memory 1204, the static memory 1206, or the mass storage device 1208 can be, or include, a machine-readable media 1222 on which is stored one or more sets of data structures or instructions 1224 (e.g., software) embodying or used by any one or more of the techniques or functions discussed herein. The instructions 1224 can also reside, completely or at least partially, within any of registers of the hardware processor 1202, the main memory 1204, the static memory 1206, or the mass storage device 1208 during execution thereof by the machine 1200. In an example, one or any combination of the hardware processor 1202, the main memory 1204, the static memory 1206, or the mass storage device 1208 can constitute the machine-readable media 1222. While the machine-readable media 1222 is illustrated as a single medium, the term “machine-readable medium” can include a single medium or multiple media (e.g., a centralized or distributed database, or associated caches and servers) configured to store the one or more instructions 1224.

The term “machine-readable medium” can include any medium that is capable of storing, encoding, or carrying instructions for execution by the machine 1200 and that cause the machine 1200 to perform any one or more of the techniques of the present disclosure, or that is capable of storing, encoding or carrying data structures used by or associated with such instructions. Non-limiting machine-readable medium examples can include solid-state memories, optical media, magnetic media, and signals (e.g., radio frequency signals, other photon-based signals, sound signals, etc.). In an example, a non-transitory machine-readable medium comprises a machine-readable medium with a plurality of particles having invariant (e.g., rest) mass, and thus are compositions of matter. Accordingly, non-transitory machine-readable media are machine readable media that do not include transitory propagating signals. Specific examples of non-transitory machine-readable media can include: non-volatile memory, such as semiconductor memory devices (e.g., electrically programmable read-only memory (EPROM), electrically erasable programmable read-only memory (EEPROM)) and flash memory devices; magnetic disks, such as internal hard disks and removable disks; magneto-optical disks; and CD-ROM and DVD-ROM disks.

In an example, information stored or otherwise provided on the machine-readable media 1222 can be representative of the instructions 1224, such as instructions 1224 themselves or a format from which the instructions 1224 can be derived. This format from which the instructions 1224 can be derived can include source code, encoded instructions (e.g., in compressed or encrypted form), packaged instructions (e.g., split into multiple packages), or the like. The information representative of the instructions 1224 in the machine-readable media 1222 can be processed by processing circuitry into the instructions to implement any of the operations discussed herein. For example, deriving the instructions 1224 from the information (e.g., processing by the processing circuitry) can include: compiling (e.g., from source code, object code, etc.), interpreting, loading, organizing (e.g., dynamically or statically linking), encoding, decoding, encrypting, unencrypting, packaging, unpackaging, or otherwise manipulating the information into the instructions 1224.

In an example, the derivation of the instructions 1224 can include assembly, compilation, or interpretation of the information (e.g., by the processing circuitry) to create the instructions 1224 from some intermediate or preprocessed format provided by the machine-readable media 1222. The information, when provided in multiple parts, can be combined, unpacked, and modified to create the instructions 1224. For example, the information can be in multiple compressed source code packages (or object code, or binary executable code, etc.) on one or several remote servers. The source code packages can be encrypted when in transit over a network and decrypted, uncompressed, assembled (e.g., linked) if necessary, and compiled or interpreted (e.g., into a library, stand-alone executable etc.) at a local machine, and executed by the local machine.

The instructions 1224 can be further transmitted or received over a communications network 1226 using a transmission medium via the network interface device 1220 utilizing any one of a number of transfer protocols (e.g., frame relay, internet protocol (IP), transmission control protocol (TCP), user datagram protocol (UDP), hypertext transfer protocol (HTTP), etc.). Example communication networks can include a local area network (LAN), a wide area network (WAN), a packet data network (e.g., the Internet), mobile telephone networks (e.g., cellular networks), plain old telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 1220 can include one or more physical jacks (e.g., Ethernet, coaxial, or phone jacks) or one or more antennas to connect to the network 1226. In an example, the network interface device 1220 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 1200, and includes digital or analog communications signals or other intangible medium to facilitate communication of such software. A transmission medium is a machine-readable medium.

Some non-limiting examples (Examples 1-20) of the present subject matter are provided as follows:

In Example 1, an electronic device, may include multiple plates, multiple plate groups, multiple plate-extra plate pairs, and multiple driver pairs. The multiple plate groups may each include a plate of the multiple plates, a memory cell group including memory cells coupled to the plate, and a digit line group including digit lines coupled to respective memory cells of the memory cell group. The multiple plate-extra plate pairs may each include a respective plate of the multiple plates and an extra plate positioned near the respective plate of the multiple plates. The multiple driver pairs may each include a plate driver and an extra plate driver respectively coupled to the plate and the extra plate of a plate-extra plate pair of the multiple plate-extra plate pairs. The plate driver may be configured to generate a plate signal to be applied to the plate. The extra plate driver may be configured to generate an extra plate signal to be applied to the extra plate.

In Example 2, the subject matter of Example 1 may optionally be configured such that the memory cells include ferroelectric memory cells.

In Example 3, the subject matter of any one or a combination of Examples 1 and 2 may optionally be configured to further include a memory controller configured to select a plate of the multiple plates and to control a memory cell access operation in the plate group of the selected plate.

In Example 4, the subject matter of Example 3 may optionally be configured such that the memory controller includes a plate controller configured to control the generation of the plate signal and the extra plate signal to be applied to the plate-extra plate pair including the selected plate for the memory cell access operation.

In Example 5, the subject matter of Example 4 may optionally be configured such that the plate controller is configured to control the generation of the extra plate signal for reducing crosstalk between the selected plate and one or more unselected plate of the multiple plates when the plate signal changes during a portion of the memory cell access operation.

In Example 6, the subject matter of Example 5 may optionally be configured such that the plate controller is configured to control the generation of the plate signal and the extra plate signal such that the plate signal and the extra plate signal are complementary signals during the portion of the memory cell access operation.

In Example 7, the subject matter of any one or any combination of Examples 4 to 6 may optionally be configured to further include sense amplifier groups respectively coupled to the multiple plate groups. The sense amplifier groups each include sense amplifiers selectively coupled to memory cells of the respective plate group through digit lines of the respective plate group.

In Example 8, the subject matter of Example 7 may optionally be configured such that the memory cell access operation is a sensing operation including a sensing phase and a precharge phase, and the plate controller is configured to control the generation of the plate signal and the generation of the extra plate signal such that the plate signal falls, and the extra plate signal rises, at a beginning of the precharge phase.

In Example 9, the subject matter of Example 7 may optionally be configured such that the memory cell access operation is a sensing operation including a sensing phase and a precharge phase, and the plate controller is configured to control the generation of the plate signal and the generation of the extra plate signal such that the plate signal rises, and the extra plate signal falls, at a beginning of the precharge phase.

In Example 10, a method is provided. The method may include performing a memory cell access operation in an electronic device. The electronic device may include: multiple plates; multiple plate groups each including a plate of the multiple plates, a memory cell group including memory cells coupled to the plate, and a digit line group including digit lines coupled to respective memory cells of the memory cell group; and multiple plate-extra plate pairs each including a plate of the multiple plates and an extra plate positioned near that plate. The performance of the memory cell access operation may include applying a plate signal to the plate and applying an extra plate signal to the extra plate.

In Example 11, the subject matter of performing the memory cell access operation in the electronic device as found in Example 10 may optionally include performing the memory cell access operation in a ferroelectric random access memory.

In Example 12, the subject matter of performing the memory cell access operation as found in any one or a combination of Examples 10 and 11 may optionally include selecting a plate from the multiple plates and accessing a memory cell in the plate group including the selected plate. The subject matter of applying the extra plate signal to the extra plate as found in any one or a combination of Examples 10 and 11 may optionally include reducing crosstalk between the selected plate and on or more unselected plates of the multiple plates by controlling the application of the extra plate signal to the extra plate positioned near the selected plate. The crosstalk is caused by the application of the plate signal to the selected plate.

In Example 13, the subject matter of any one or any combination of Examples 10 to 12 may optionally further include controlling the application of the plate signal and the application of the extra plate signal such that the plate signal and the extra plate signal change simultaneously during a portion of the memory cell access operation.

In Example 14, the subject matter of controlling the application of the plate signal and the application of the extra plate signal as found in Example 13 may optionally include controlling the application of the plate signal and the application of the extra plate signal such that the plate signal and the extra plate signal are complementary signals during the portion of the memory cell access operation.

In Example 15, the subject matter of performing the memory cell access operation as found in any one or a combination of Examples 13 and 14 may optionally include performing a sensing operation including a sensing phase and a precharge phase.

In Example 16, the subject matter of Example 15 may optionally further include generating the plate signal and the extra plate signal to be applied to the selected plate and the extra plated positioned near the selected plate, respectively, such that the plate signal falls, and the extra plate signal rises, at a beginning of the precharge phase.

In Example 17, the subject matter of Example 15 may optionally further include generating the plate signal and the extra plate signal to be applied to the selected plate and the extra plated positioned near the selected plate, respectively, such that the plate signal rises, and the extra plate signal falls, at a beginning of the precharge phase.

In Example 18, a method is provided. The method may include providing an electronic device including: multiple plates; multiple plate groups each including a plate of the multiple plates, a memory cell group including memory cells coupled to the plate, and a digit line group including digit lines coupled to respective memory cells of the memory cell group; and multiple plate drivers each configured to generate a plate signal to be applied to a plate of the multiple plates. The method may further include providing multiple extra plates each being an extra plate layer positioned over a plate of the multiple plates and providing extra plate drivers each configured to generate an extra plate signal to be applied to an extra plate of the multiple extra plates.

In Example 19, the subject matter of providing the electronic device as found in Example 18 may optionally include providing a ferroelectric random access memory device.

In Example 20, the subject matter of any one or a combination of Examples 18 and 19 may optionally further include providing a plate controller configured to control a memory cell access operation for which a plate of the multiple plate is selected for accessing one or more of the memory cells coupled to the selected plate, including controlling generation of the plate signals and the extra plate signals for reducing crosstalk between the selected plate and one or more unselected plates of the multiple plates.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or discussed. However, the present inventors also contemplate examples in which only those elements shown or discussed are provided. Moreover, the present inventors also contemplate examples using any combination or permutation of those elements shown or discussed (or one or more aspects thereof), either with respect to a particular example (or one or more aspects thereof), or with respect to other examples (or one or more aspects thereof) shown or discussed herein.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either coupled, or directly coupled, unless otherwise indicated.

The above description is intended to be illustrative, and not restrictive. For example, the above-discussed examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. An electronic device, comprising:
multiple plates;
multiple plate groups each including a plate of the multiple plates, a memory cell group including memory cells coupled to the plate, and a digit line group including digit lines coupled to respective memory cells of the memory cell group;
multiple plate-extra plate pairs each including a respective plate of the multiple plates and an extra plate positioned near the respective plate of the multiple plates; and
multiple driver pairs each including a plate driver and an extra plate driver respectively coupled to the plate and the extra plate of a plate-extra plate pair of the multiple plate-extra plate pairs, the plate driver configured to generate a plate signal to be applied to the plate, the extra plate driver configured to generate an extra plate signal to be applied to the extra plate.

2. The electronic device of claim 1, wherein the memory cells comprise ferroelectric memory cells.

3. The electronic device of claim 1, further comprising a memory controller configured to select a plate of the multiple plates and to control a memory cell access operation in the plate group of the selected plate.

4. The electronic device of claim 3, wherein the memory controller comprises a plate controller configured to control the generation of the plate signal and the extra plate signal to be applied to the plate-extra plate pair including the selected plate for the memory cell access operation.

5. The electronic device of claim 4, wherein the plate controller is configured to control the generation of the extra plate signal for reducing crosstalk between the selected plate and one or more unselected plate of the multiple plates when the plate signal changes during a portion of the memory cell access operation.

6. The electronic device of claim 5, wherein the plate controller is configured to control the generation of the plate signal and the extra plate signal such that the plate signal and the extra plate signal are complementary signals during the portion of the memory cell access operation.

7. The electronic device of claim 4, further comprising sense amplifier groups respectively coupled to the multiple plate groups, the sense amplifier groups each including sense amplifiers selectively coupled to memory cells of the respective plate group through digit lines of the respective plate group.

8. The electronic device of claim 7, wherein the memory cell access operation is a sensing operation including a sensing phase and a precharge phase, and the plate controller is configured to control the generation of the plate signal and the generation of the extra plate signal such that the plate signal falls, and the extra plate signal rises, at a beginning of the precharge phase.

9. The electronic device of claim 7, wherein the memory cell access operation is a sensing operation including a sensing phase and a precharge phase, and the plate controller is configured to control the generation of the plate signal and the generation of the extra plate signal such that the plate signal rises, and the extra plate signal falls, at a beginning of the precharge phase.

10. A method, comprising:
performing a memory cell access operation in an electronic device including:
multiple plates;
multiple plate groups each including a plate of the multiple plates, a memory cell group including memory cells coupled to the plate, and a digit line group including digit lines coupled to respective memory cells of the memory cell group; and
multiple plate-extra plate pairs each including a plate of the multiple plates and an extra plate positioned near that plate,
wherein the performance of the memory cell access operation includes:
applying a plate signal to the plate; and
applying an extra plate signal to the extra plate.

11. The method of claim 10, wherein performing the memory cell access operation in the electronic device comprises performing the memory cell access operation in a ferroelectric random access memory.

12. The method of claim 10, wherein performing the memory cell access operation comprises:
selecting a plate from the multiple plates; and
accessing a memory cell in the plate group including the selected plate, and applying the extra plate signal to the extra plate comprises reducing crosstalk between the selected plate and on or more unselected plates of the multiple plates by controlling the application of the extra plate signal to the extra plate positioned near the selected plate, the crosstalk caused by the application of the plate signal to the selected plate.

13. The method of claim 12, further comprising controlling the application of the plate signal and the application of the extra plate signal such that the plate signal and the extra plate signal change simultaneously during a portion of the memory cell access operation.

14. The method of claim 13, wherein controlling the application of the plate signal and the application of the extra plate signal comprise controlling the application of the plate signal and the application of the extra plate signal such that the plate signal and the extra plate signal are complementary signals during the portion of the memory cell access operation.

15. The method of claim 14, wherein performing the memory cell access operation comprises performing a sensing operation including a sensing phase and a precharge phase.

16. The method of claim 15, further comprising generating the plate signal and the extra plate signal to be applied to the selected plate and the extra plated positioned near the selected plate, respectively, such that the plate signal falls, and the extra plate signal rises, at a beginning of the precharge phase.

17. The method of claim 15, further comprising generating the plate signal and the extra plate signal to be applied to the selected plate and the extra plated positioned near the selected plate, respectively, such that the plate signal rises, and the extra plate signal falls, at a beginning of the precharge phase.

18. A method, comprising:
providing an electronic device including:
multiple plates;
multiple plate groups each including a plate of the multiple plates, a memory cell group including memory cells coupled to the plate, and a digit line group including digit lines coupled to respective memory cells of the memory cell group; and
multiple plate drivers each configured to generate a plate signal to be applied to a plate of the multiple plates;
providing multiple extra plates each being an extra plate layer positioned over a plate of the multiple plates; and
providing extra plate drivers each configured to generate an extra plate signal to be applied to an extra plate of the multiple extra plates.

19. The method of claim 18, wherein providing the electronic device comprises providing a ferroelectric random access memory device.

20. The method of claim 19, further comprising providing a plate controller configured to control a memory cell access operation for which a plate of the multiple plate is selected for accessing one or more of the memory cells coupled to the selected plate, including controlling generation of the plate signals and the extra plate signals for reducing crosstalk between the selected plate and one or more unselected plates of the multiple plates.
